(19) United States
(12) Patent Application Publication
(10) Pub. No.: US 2013/0187233 A1
(43) Pub. Date: Jul. 25, 2013

(54) SEMICONDUCTOR MEMORY DEVICES

(71) Applicants: Jaesun YUN, Anyang-si (KR); Jeongseok NAM, Hwaseong-si (KR); Jinhyun SHIN, Suwon-si (KR)

(72) Inventors: Jaesun YUN, Anyang-si (KR); Jeongseok NAM, Hwaseong-si (KR); Jinhyun SHIN, Suwon-si (KR)

(73) Assignee: SAMSUNG ELECTRONICS CO., LTD., Suwon-si (KR)

(21) Appl. No.: 13/584,193

(22) Filed: Aug. 13, 2012

(30) Foreign Application Priority Data
Jan. 19, 2012 (KR) 10-2012-0006350

(51) Int. Cl. H01L 27/105

(52) U.S. Cl. 257/368; 257/E27.081

(57) ABSTRACT

A semiconductor memory device may include: a well impurity layer including a cell array region and a well drive region adjacent to the cell array region, the well impurity layer having a first conductivity type; at least one word line on the well impurity layer; at least one bit line crossing the at least one word line on the well impurity layer of the cell array region, the at least one bit line connected to a drain region in the well impurity layer, and the drain region having a second conductivity type; and a well drive line crossing the at least one word line on the well impurity layer of the well drive region, the well drive line connected to the well impurity layer of the first conductivity type.

### CROSS-REFERENCE TO RELATED APPLICATIONS

This U.S. non-provisional patent application claims priority under 35 U.S.C. §119 to Korean Patent Application No. 10-2012-0006350, filed on Jan. 19, 2012, the entirety of which is incorporated by reference herein.

### BACKGROUND

Inventive concepts relate to semiconductor memory devices and, more particularly, to NAND flash memory devices.

Semiconductor memory devices may be classified into volatile memory devices and non-volatile memory devices. Volatile memory devices lose their stored data when their power supplies are interrupted. In contrast, non-volatile memory devices retain their data stored data even when their power supplies are interrupted.

Flash memory devices may be classified into a NOR type and a NAND type. The NOR type flash memory devices may control memory cells independently, which may enhance operation speeds. However, at least one contact may be required per two memory cells in the NOR type flash memory device. As such, the NOR type flash memory device may have a large cell area. On the contrary, the NAND type flash memory device may control a string having a plurality of memory cells. As such, the NAND type flash memory device may have an advantage of high integration.

### SUMMARY

At least one example embodiment of inventive concepts may provide semiconductor memory devices with improved reliability.

According to at least one example embodiment, a semiconductor memory device may include: a well impurity layer including a cell array region and a well drive region adjacent to the cell array region, the well impurity layer having a first conductivity type; at least one word line on the well impurity layer; at least one bit line crossing the at least one word line on the well impurity layer of the cell array region, the at least one bit line connected to a drain region in the well impurity layer, and the drain region having a second conductivity type; and a well drive line crossing the at least one word line on the well impurity layer of the well drive region, the well drive line connected to the well impurity layer of the first conductivity type.

In at least one example embodiment, the well drive line is between the at least one bit line and an adjacent bit line from a plan view perspective; and a width of the well drive line is smaller than a distance between the at least one bit line and the adjacent bit line.

In at least one example embodiment, a width of the well drive line is greater than a width of the at least one bit line.

In at least one example embodiment, the well drive line is between the at least one bit line and the at least one word line from a cross-sectional perspective view.

In at least one example embodiment, the well drive line is disposed over a center portion of the well impurity layer.

In at least one example embodiment, the well drive line is disposed over an edge portion of the well impurity layer and the at least one bit line is disposed over a center portion of the well impurity layer.

In at least one example embodiment, a semiconductor memory device may further include: a well pick-up region in the well impurity layer, the well pick-up region having the first conductivity type, and an impurity concentration of the well pick-up region being greater than that of the well impurity layer; and a contact plug connecting the well drive line to the well pick-up region.

In at least one example embodiment, semiconductor memory device may further include: at least one string selection line on the well impurity layer and parallel to the at least one word line, and the drain region and the well pick-up region are disposed at a side of the at least one string selection line, the drain region and the well pick-up region being spaced apart from the at least one string selection line.

In at least one example embodiment, a semiconductor memory device may further include: a common source region in the well impurity layer of the cell array region, the common source region having the second conductivity type; and a common source conductive pad covering a top surface of the at least one bit line, the common source conductive pad applying a desired voltage to the common source region.

According to at least one example embodiment, a semiconductor memory device may include: a well impurity layer of a first conductivity type; at least one word line on the well impurity layer; at least one bit line crossing the at least one word line, the at least one bit line connected to a drain region formed in the well impurity layer, the drain region having a second conductivity type; and a well drive line crossing the at least one bit line at a height different from that of the at least one bit line with respect to a top surface of the well impurity layer, the well driving line being connected to the well impurity layer.

In at least one example embodiment, the well drive line is between the at least one bit line and the at least one word line from a cross-sectional perspective view.

In at least one example embodiment, a semiconductor memory device may further include: a well pick-up in the well impurity layer, the well pick-up region having the first conductivity type, and an impurity concentration of the well pick-up region being greater than that of the well impurity layer; and a contact plug connecting the well drive line to the well pick-up region.

In at least one example embodiment, the well pick-up region is in an edge portion of the well impurity layer.

In at least one example embodiment, a semiconductor memory device may further include: at least one string selection line on the well impurity layer and substantially parallel to the at least one word line, the well drive line being disposed over the at least one string selection line.

In at least one example embodiment, the well pick-up region is in a portion of the well impurity layer at a side of the at least one string selection line from a plan view perspective.

According to at least one example embodiment, a semiconductor memory device may include: a well impurity layer; a word line on the well impurity layer; a bit line on the well impurity layer, the bit line crossing the word line; and a well drive region including a well drive line, the well drive line being parallel to one of the word line and the bit line, and the well drive line and the bit line being at different vertical levels in the semiconductor memory device.

In at least one example embodiment, a semiconductor memory device may further include: a region of the well impurity layer having a first conductivity type connected to the bit line; and a region of well impurity layer having a second conductivity type connected to the well drive line, the second conductivity type being opposite the first conductivity type.

In at least one example embodiment, a semiconductor memory device may further include: a dummy pattern on the well drive region; and a common source line connected to the dummy pattern, the common source line connected to a region having the first conductivity type in the well impurity layer.

In at least one example embodiment, the well drive region is in a center portion of the well impurity layer.

In at least one example embodiment, the well drive region is in an edge portion of the well impurity layer.

### BRIEF DESCRIPTION OF THE DRAWINGS

Inventive concepts will become more apparent in view of the attached drawings and accompanying detailed description.

FIG. 1 is a schematic block diagram illustrating a semiconductor memory device according to at least one example embodiment of inventive concepts;

FIG. 2 is a schematic circuit diagram illustrating a semiconductor memory device according to at least one example embodiment of inventive concepts;

FIG. 3 is a plan view illustrating a semiconductor memory device according to at least one example embodiment of inventive concepts;

FIGS. 4A to 4C are cross-sectional views taken along lines I-I′, II-II′, and III-III′ of FIG. 3, respectively;

FIG. 5 is a plan view illustrating a semiconductor memory device according to at least one example embodiment of inventive concepts;

FIGS. 6A and 6B are cross-sectional views taken along lines I-I′ and II-IF of FIG. 5, respectively;

FIG. 7 is a plan view illustrating a semiconductor memory device according to at least one example embodiment of inventive concepts;

FIGS. 8A and 8B are cross-sectional views taken along lines I-I′ and II-IF of FIG. 7, respectively;

FIG. 9 is a schematic block diagram illustrating an example of memory systems including semiconductor memory devices according to at least one example embodiment of inventive concepts;

FIG. 10 is a schematic block diagram illustrating an example of memory cards including semiconductor memory devices according to at least one example embodiment of inventive concepts; and

FIG. 11 is a schematic block diagram illustrating an example of information processing systems including semiconductor memory devices according to at least one example embodiment of inventive concepts.

### DETAILED DESCRIPTION OF EXAMPLE EMBODIMENTS

Inventive concepts will now be described more fully hereinafter with reference to the accompanying drawings, in which exemplary embodiments of inventive concepts are shown. The advantages and features of inventive concepts and methods of achieving them will be apparent from the following exemplary embodiments that will be described in more detail with reference to the accompanying drawings. It should be noted, however, that inventive concepts are not limited to the following exemplary embodiments, and may be implemented in various forms. Accordingly, the exemplary embodiments are provided only to disclose inventive concepts and let those skilled in the art know the category of inventive concepts. In the drawings, example embodiments of inventive concepts are not limited to the specific examples provided herein and are exaggerated for clarity.

The terminology used herein is for the purpose of describing particular embodiments only and is not intended to limit example embodiments. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, example embodiments in the detailed description will be described with sectional views as ideal exemplary views of inventive concepts. Accordingly, shapes of the exemplary views may be modified according to manufacturing techniques and/or allowable errors. Therefore, example embodiments of inventive concepts are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of inventive concepts.

Spatially relative terms, such as “below”, “beneath”, “lower”, “above”, “upper”, “over”, and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of inventive concepts. Exemplary embodiments of aspects of inventive concepts explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

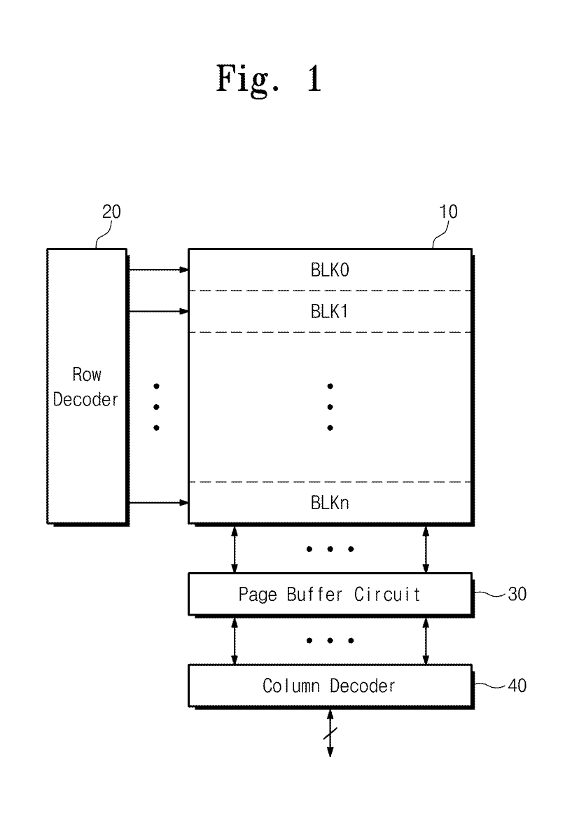

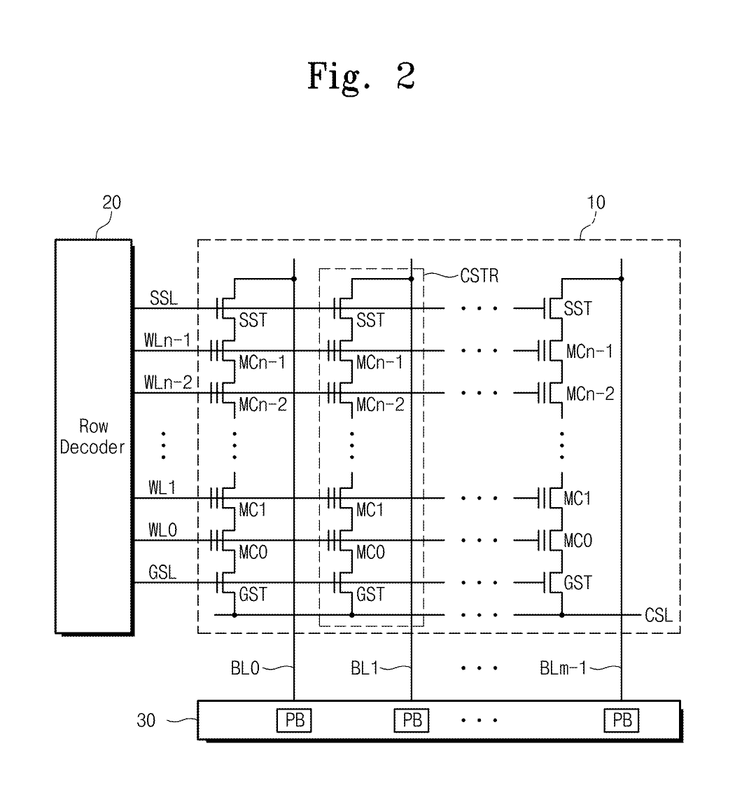

FIG. 1 is a schematic block diagram illustrating a semiconductor memory device according to at least one example embodiment of inventive concepts. FIG. 2 is a schematic circuit diagram illustrating a semiconductor memory device according to at least one example embodiment of inventive concepts.

Referring to FIGS. 1 and 2, a NAND type semiconductor memory device may include a memory cell array 10, a row decoder 20, a page buffer circuit 30, and a column decoder 40.

The memory cell array 10 may include a plurality of memory blocks BLK0 to BLKn and the memory blocks BLK0 to BLKn may include a plurality of word lines, a plurality of bit lines, and a plurality of memory cells and store data. In more detail, as illustrated in FIG. 2, the memory cell array 10 may include a plurality of cell strings (or NAND strings) which are connected to the bit lines BL0 to BLm−1, respectively. The cell string of each column may include at least one string selection transistor SST and at least one ground selection transistor GST. A plurality of the memory cells (or memory cell transistors) MC0 to MCn−1 may be connected in series between the selection transistors SST and GST. The cell strings may be electrically connected to corresponding bit lines BL0 to BLm−1, respectively.

The row decoder 20 selects one of the memory blocks BLK0 to BLKn of the memory cell array 10 and then selects one of the word lines of the selected memory block according to address information. The row decoder 20 provides word line voltages generated from a voltage generating circuit (not shown) to the selected word line and non-selected word lines, respectively, in response to control of a control circuit (not shown).

The page buffer circuit 30 may temporarily store data that will be stored in the memory cells or sense data stored in the memory cells according to operation modes. The page buffer circuit 30 may be operated as a write driver circuit during a program operation mode and be operated as a sense amplifier circuit during a read operation mode. As illustrated in FIG. 2, the page buffer circuit 30 may include page buffers PB respectively connected to the bit lines or bit line-pairs.

The column decoder 40 may provide a data transfer path between the page buffer circuit 30 and an external circuit (e.g. a memory controller).

In the semiconductor memory device described above, the memory cell array 10 performs a read operation and a program operation with a page as a unit and performs an erase operation with the memory block as a unit. The operations of the semiconductor memory device will be mentioned briefly. The program operation storing data in a selected memory cell may be performed by applying a program voltage VPGM to the selected word line and applying a pass voltage VPASS to the non-selected word lines. Here, the program voltage VPGM may be a high voltage within a range of about 10V (volts) to 20V and the pass voltage VPASS may be a desired (or alternatively, predetermined) voltage capable of turning on the memory cell transistors MC0 to MCn−1. Additionally, 0V may be applied to a selected bit line and a Vbl (e.g. a voltage Vcc, that is, a power voltage) may be applied to non-selected bit lines when the program operation is performed. Furthermore, a ground voltage GND may be applied to ground selection lines GSL and a voltage Vcc may be applied to a string selection line SSL. A voltage within a range of about 1.5V to about 2.0V may be applied to a common source line CSL and the ground voltage may be applied to a semiconductor substrate.

Under the voltage condition described above, a selected string selection transistor SST and the memory cell transistors MC0 to MCn−1 in a selected cell string CSTR may be turned on. Thus, channels of the memory cell transistors MC0 to MCn−1 in a selected cell string CSTR may have a voltage (i.e. 0V) substantially equal to the voltage applied to the selected bit line BL. Here, since the program voltage VPGM of the high voltage is applied to the selected word line, Fowler-Nordheim tunneling (F-N tunneling) may occur in the selected memory cell transistor. Thus, data may be written in the selected memory cell transistor.

The erase operation may be performed by applying the ground voltage (e.g., 0V) to the word lines WL0 to WLn−1 and applying an erase voltage Verase (e.g. about 18V to about 20V) to the semiconductor substrate on which the memory cell transistor MC0 to MCn−1 are formed. The string selection line SSL, the ground selection line GSL and the common source line CSL may be floated during the erase operation. When the voltages described above are applied to signal lines of the memory cell array 10, charges stored in the memory cell transistors MC0 to MCn−1 may be discharged into the semiconductor substrate.

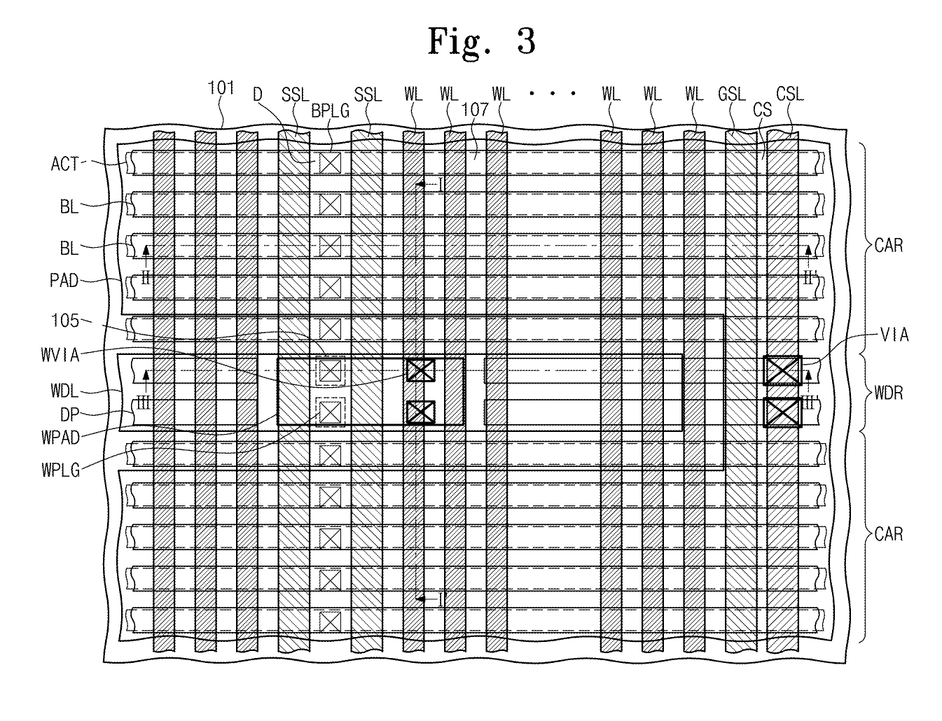

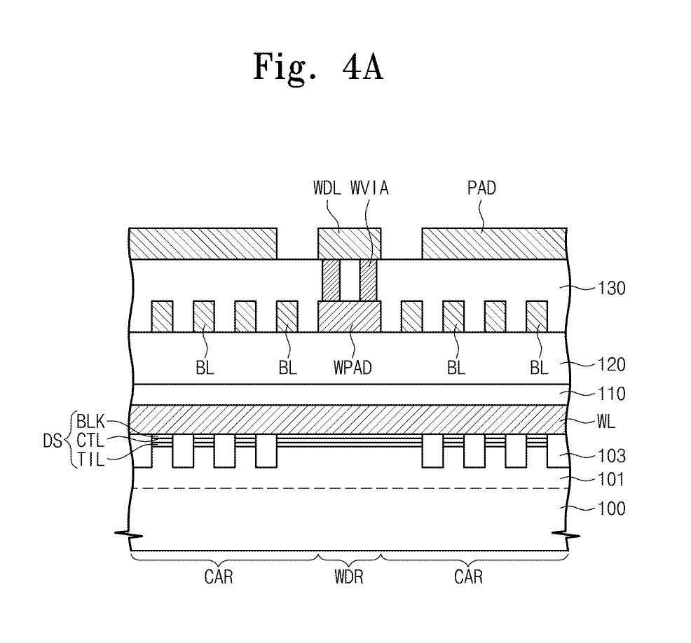

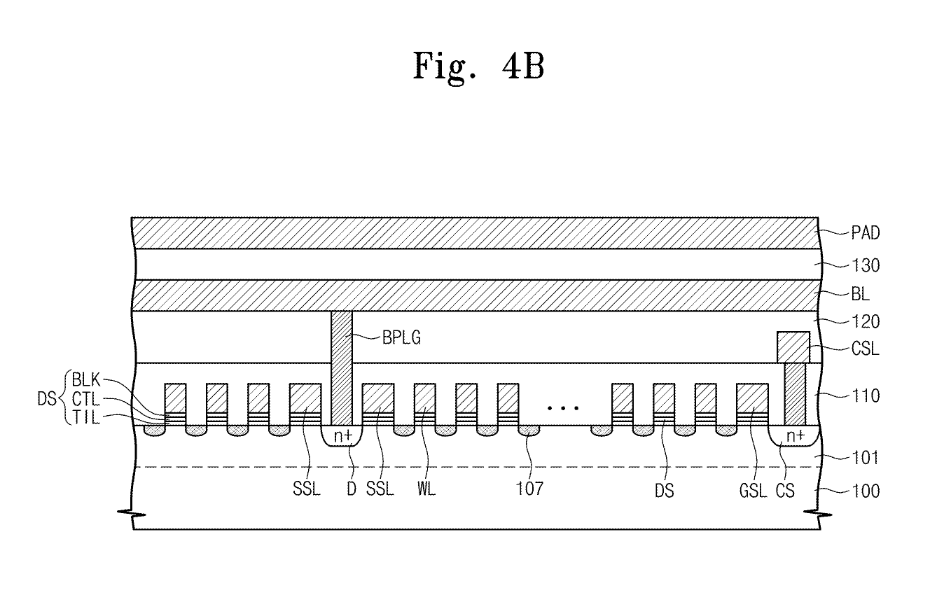

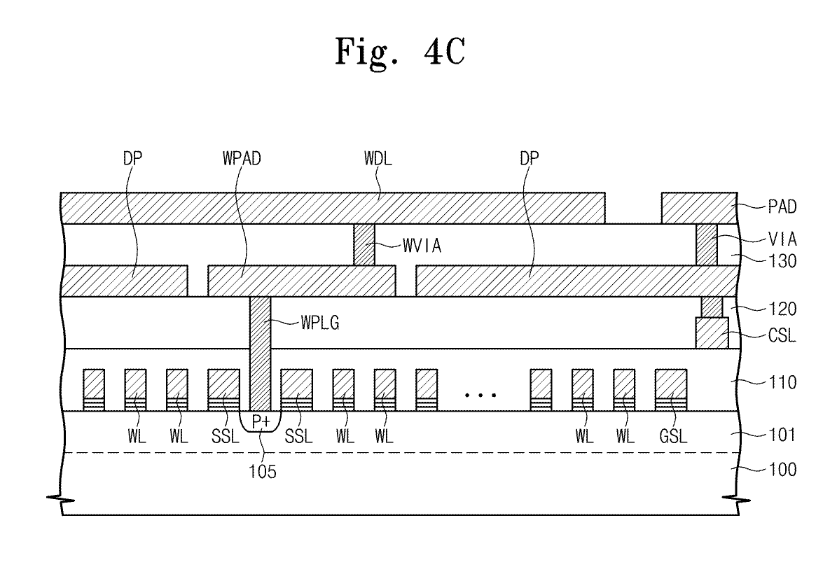

A semiconductor memory device according to at least one example embodiment will be described with reference to FIGS. 3, 4A, 4B, and 4C.

FIG. 3 is a plan view illustrating a semiconductor memory device according to at least one example embodiment of inventive concepts. FIGS. 4A to 4C are cross-sectional views illustrating a semiconductor memory device according to at least one example embodiment of inventive concepts. FIGS. 4A to 4C are cross-sectional views taken along lines I-I′, II-II′, and III-III′ of FIG. 3, respectively.

Referring to FIGS. 3 and 4A to 4C, a semiconductor substrate 100 includes cell array regions CAR and a well drive region WDR. In at least one example embodiment, the well drive region WDR may be disposed between the cell array regions CAR adjacent to each other. The semiconductor substrate 100 may be a silicon substrate, a silicon-germanium substrate, a germanium substrate, or an epitaxial layer grown on a single-crystalline silicon substrate.

The semiconductor substrate 100 includes a well impurity layer 101 of a first conductivity type and the well impurity layer 101 is formed on the semiconductor substrate 100 of the cell array regions CAR and the well drive region WDR. The well impurity layer 101 may be formed by doping impurities of the first conductivity type into the semiconductor substrate 100. In at least one example embodiment, the semiconductor substrate 100 may further include an N-type well region (not shown). The well impurity layer 101 may be a pocket P-type well region formed in the N-type well region.

In at least one example embodiment, peripheral circuits (e.g. PMOS and NMOS transistors) and the memory cell arrays in semiconductor memory device may be formed on the semiconductor substrate 100 of the first conductivity type. Here, the peripheral circuits may be formed on the semiconductor substrate 100 of the first conductivity type. And the memory cell arrays may be formed on the well impurity layer 101 of the first conductivity type which is formed in a well region (not shown) of a second conductivity type. In other words, the memory cell arrays may be formed on the pocket P-type well region formed in the N-type well region (not shown).

Because the memory cell arrays are formed on the well impurity layer 101 of the first conductivity type, when the erase operation of the semiconductor memory device is performed, the erase voltage may be limitedly applied to the memory cell arrays. Thus, it is possible to minimize (or alternatively, prevent) application of the erase voltage to the peripheral circuits. In other words, the erase voltage (e.g. about 18V to about 20V) may be selectively applied to the well impurity layer 101.

In more detail, the well impurity layer 101 includes a center portion and an edge portion around the center portion. In at least one example embodiment, the well drive region WDR may be disposed in the center portion of the well impurity layer 101 and the cell array regions CAR may be disposed in the edge portion of the well impurity layer 101.

Referring to FIGS. 4A and 4B, in the cell array regions CAR, the well impurity layer 101 may include active regions ACT having linear shapes which are defined by device isolation layers 103. The active regions ACT are disposed in parallel with each other at a desired (or alternatively, predetermined) interval in the cell array region CAR.

A plurality of word lines WL, a string selection line SSL, and a ground selection line GSL are disposed on the well impurity layer 101 and cross over the active regions ACT. The word lines WL are used as gate electrodes of memory cells. The string and ground selection lines SSL and GSL are used as gate electrodes of the string and ground selection transistors SST and GST of FIG. 2, respectively.

In at least one example embodiment, impurity regions 107 may be formed in the well impurity layer 101 in the active regions ACT between the word lines WL and between the word line WL and each of the selection lines SSL and GSL. The impurity regions 107 may have a conductivity type different from the first conductivity type of the well impurity layer 101. The impurity regions 107 may be used as source/drain regions of the memory cell transistors. In at least one other example embodiment, the well impurity layer 101 under the word lines WL may be inverted by voltages applied to the word lines WL, thereby forming channel regions. The channel regions under the word lines WL may extend in the well impurity layer 101 between the word lines WL by a fringe field. The fringe field may occur as a consequence of the voltages applied to the word lines WL. The extending channel regions may be overlapped with each other. The overlapped channel regions between the word lines WL and between the word line and each of the selection lines SSL and GSL may be used as source and drain electrodes of the memory cell transistors. In other words, the memory cells may be connected to in series by the extending channel regions.

A data storing layer DS may be disposed between the well impurity layer 101 and each of the word lines WL. For example, the data storing layer DS may include at least one of a charge trap insulating layer, a floating gate electrode, and an insulating layer including conductive nano dots. If the data storing layer DS includes the charge trap insulating layer CTL, the data stored in the data storing layer DS may be changed by F-N tunneling. The F-N tunneling is caused by a voltage difference between the well impurity layer 101 and the word line WL.

In at least one example embodiment, the data storing layer DS may include a tunnel insulating layer TIL, the charge trap insulating layer CTL, and a blocking insulating layer BLK that are sequentially stacked. The tunnel insulating layer TIL may be formed of a material having a dielectric constant lower than that of the blocking insulating layer BLK. For example, the tunnel insulating layer TIL may include at least one of oxide, nitride, and oxynitride. The charge trap insulating layer CTL may include an insulating layer (e.g. a silicon nitride layer) having charge trap sites or an insulating layer including conductive particles. In at least one example embodiment, the tunnel insulating layer TIL may be a silicon oxide layer, the charge trap insulating layer CTL may be a silicon nitride layer, and the blocking insulating layer BLK may be an insulating layer including an aluminum oxide layer. The blocking insulating layer BLK may include at least one of a silicon oxide layer, a silicon nitride layer, a silicon oxynitride layer, and a high-k dielectric layer. The blocking insulating layer BLK may be single-layered or multi-layered. The high-k dielectric layer may be an insulating material having a dielectric constant higher than that of a silicon oxide layer. The high-k dielectric layer may include at least one of a tantalum oxide layer, titanium oxide layer, a hafnium oxide layer, a zirconium oxide layer, an aluminum oxide layer, a yttrium oxide layer, a niobium oxide layer, a cesium oxide layer, an indium oxide layer, an iridium oxide layer, a BST layer, and a PZT layer.

A drain region D may be formed in each of the active regions ACT at a side of the string selection line SSL. A common source region CS may be formed in each of the active regions ACT at a side of the ground selection line GSL. The drain region D and the common source region CS may have a conductivity type different from the first conductivity type of the well impurity layer 101. The drain region D and the common source region CS may be formed by implanting impurities of the second conductivity type (e.g. N-type) into the well impurity layer 101. An impurity concentration of each of the drain region D and the common source region CS may be greater than that of the impurity region 107 between the word lines WL.

A common source line CSL may be disposed at a side of the ground selection line GSL. The common source line CSL may connect the common source regions CS of the ground selection transistors GST of FIG. 2 to each other. The common source line CSL may extend in a direction parallel to the word lines WL. In at least one example embodiment, the common source line CSL may be disposed to cross the well drive region WDR. The common source line CSL may be disposed on a first interlayer insulating layer 110 covering the plurality of word lines WL and the string selection line SSL, and the ground selection line GSL. The common source line CSL may be electrically connected to the common source regions CS through contact source plugs penetrating the first interlayer insulating layer 110. The common source regions CS of the cell strings may be in an equipotential state.

In at least one example embodiment, bit lines BL are disposed to cross over the word lines WL and over the semiconductor substrate 100 of the cell array regions CAR. The bit lines BL crossing the word lines WL may be disposed on a second interlayer insulating layer 120 covering the common source line CSL. The bit lines BL may be connected to the drain regions D of the string selection transistors through bit line contact plugs BPLG, respectively.

Referring to FIGS. 4A and 4C, a well pick-up region 105 may be formed in the well impurity layer 101 at a side of the string selection line SSL in the well drive region WDR. The well pick-up region 105 may be locally formed in a region of the well impurity layer 101 which is connected to a well contact plug WPLG. The well pick-up region 105 may have the same conductivity type as the well impurity layer 101. The well pick-up region 105 may be formed by implanting impurities of the first conductivity type into the well impurity layer 101. An impurity concentration of the well pick-up region 105 may be greater than that of the well impurity layer 101.

The well pick-up region 105 may be electrically connected to a well drive line WDL through the well contact plug WPLG and a well contact pad WPAD. Applying a desired (or alternatively, predetermined) voltage to the well pick-up region 105 through the well drive line WDL may minimize (or alternatively, prevent) malfunctions in the semiconductor memory device uniformly provide the voltage to the well impurity layer 101.

The well drive pad WPAD may be disposed on the second interlayer insulating layer 120 of the well drive region WDR. Additionally, dummy patterns DP may be disposed on the second interlayer insulating layer 120 of the well drive region WDR. The dummy patterns DP and the well drive pad WPAD may be formed of the same conductive material as the bit lines BL.

In at least one example embodiment, the well drive line WDL is disposed over the semiconductor substrate 100 of the well drive region WDR. The well drive line WDL may be disposed on a third interlayer insulating layer 130 covering the bit lines BL. The well drive line WDL may be connected to the well drive pad WPAD through a well drive via WVIA.

A well bias voltage may be uniformly applied to the well impurity layer 101 through the well drive line WDL during an operation of the semiconductor memory device, so that a voltage drop may be minimized (or alternatively, prevented) in the memory cell transistors. In more detail, when the program and read operations of the semiconductor memory device are performed, a ground voltage as the well bias voltage may be applied to the well drive line WDL. When the erase operation of the semiconductor memory device is performed, the erase voltage (e.g. about 20V) as the well bias voltage is applied to the well drive line WDL.

In at least one example embodiment, the well drive line WDL is disposed to cross over the word lines WL. The well drive line WDL is not overlapped with the bit lines BL from a plan view perspective. In other words, the well drive line WDL may be disposed between the bit lines BL adjacent to each other in a plan view, and a width of the well drive line WDL may be smaller than a distance between the bit lines BL adjacent to each other. In other words, the well drive line WDL may be locally disposed in the well drive region WDR between the cell array regions CAR. The width of the well drive line WDL may be greater than a width of the bit line BL. The well drive line WDL may be connected to the well drive pad WPAD through the well drive via WVIA and be electrically connected to the well impurity layer 101.

In at least one example embodiment, a vertical distance from a top surface of the well impurity layer 101 to the well drive line WDL may be greater than a vertical distance from the top surface of the well impurity layer 101 to the bit line BL. Alternatively, the well drive line WDL and the bit lines BL may be directly disposed on the second interlayer insulating layer 120 since the well drive line WDL is not overlapped with the bit lines BL in a plan view. In other words, the vertical distance from the top surface of the well impurity layer 101 to the well drive line WDL may be substantially equal to the vertical distance from the top surface of the well impurity layer 101 to the bit line BL.

According to related art devices, the well drive line WDL may be overlapped with the bit lines BL in a plan view. That is, the well drive line WDL may cover the bit lines BL. In this case, the ground voltage may be applied to the well drive line WDL and the power voltage Vcc may be applied to non-selected bit lines BL disposed under the well drive line WDL when the read and program operations are performed. As a result, the non-selected bit lines BL may be vertically coupled to the well drive line WDL during the operation of the semiconductor memory device. In other words, the voltage applied to the bit line BL may fluctuate by a parasitic capacitance between the bit line BL and the well drive line WDL vertically adjacent to each other. Thus, the voltage applied to the non-selected bit lines BL may fluctuate and an error may occur in the operation of the semiconductor memory device. In contrast, a device according to at least one example embodiment of inventive concepts may minimize (or alternatively, prevent) the parasitic capacitance between the well drive line WDL and the bit lines BL because the well drive line WDL is not overlapped with the bit lines BL in a plan view.

Additionally, according to at least one example embodiment, a common source pad PAD may be disposed over the bit lines BL. The common source pad PAD and the well drive line WDL may be disposed on the third insulating layer 130. The common source pad PAD may be electrically connected to the common source line CSL through the dummy patterns DP and a common source via VIA disposed in the well drive region WDR.

In at least one example embodiment, the ground voltage may not be applied to the common source pad PAD covering the bit lines BL during the operation of the semiconductor memory device. Thus, it is possible to suppress an operation error caused by a vertical parasitic capacitance between the bit line BL and the common source pad PAD.

In at least one example embodiment, the bit line contact plug BPLG, the well contact plug WPLG, the well drive via WVIA, the common source via VIA may be formed of at least one of conductive materials, for example, metal (e.g. tungsten, aluminum, titanium, tantalum, etc.), a conductive metal nitride (e.g. titanium nitride, tantalum nitride, etc.), a doped semiconductor material (e.g. doped silicon, doped germanium, doped silicon-germanium, etc.), and metal silicides.

In at least one example embodiment, the bit lines BL, the well drive line WDL, and the common source pad PAD may include a metal. For example, the bit lines BL, the well drive line WDL, and the common source pad PAD may include a metal such as copper, tungsten, aluminum, titanium, and/or tantalum, etc.

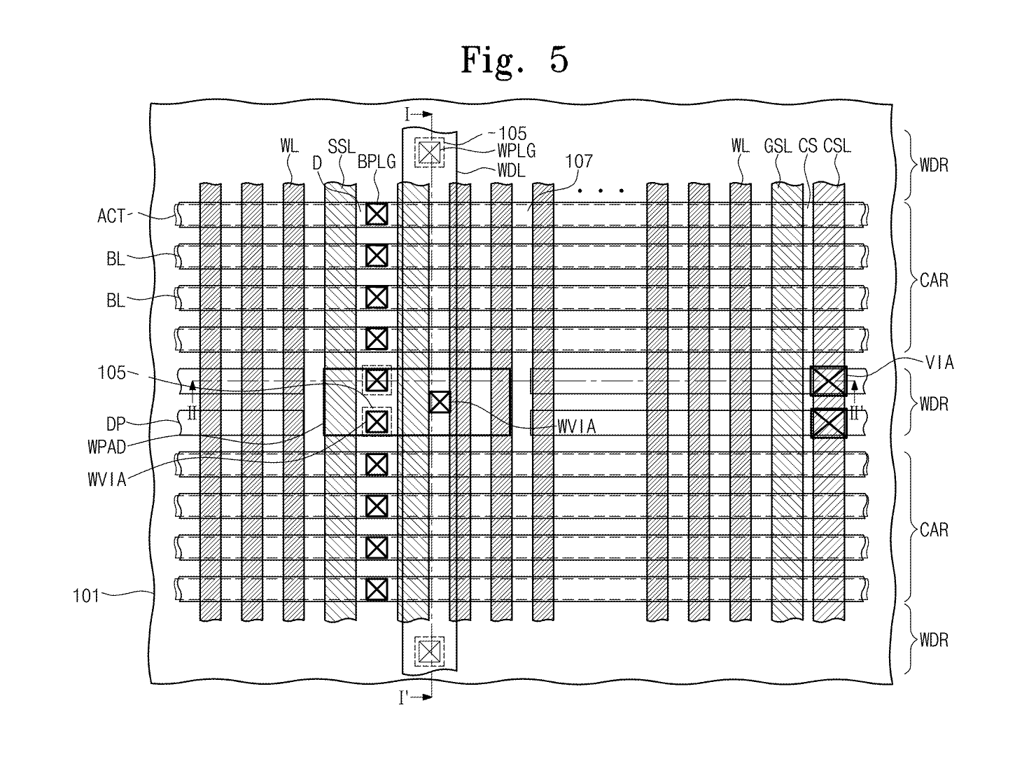

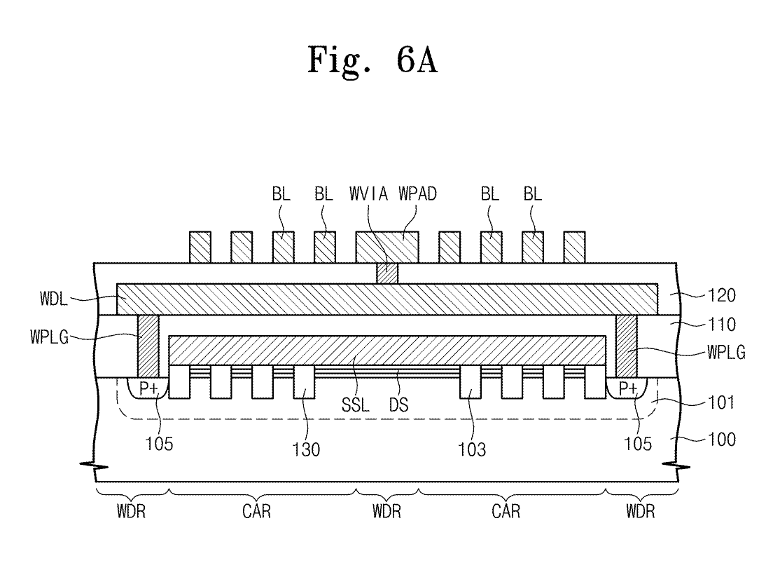

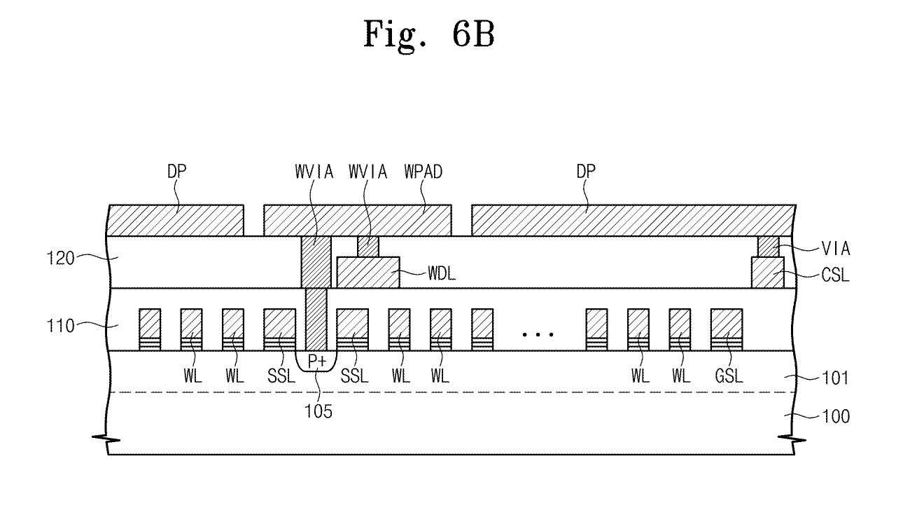

Hereinafter, a semiconductor memory device according to another example embodiment of inventive concepts will be described with reference to FIGS. 5, 6A, and 6B.

FIG. 5 is a plan view illustrating a semiconductor memory device according to at least one example embodiment of inventive concepts. FIGS. 6A and 6B are cross-sectional views illustrating a semiconductor memory device according to at least one example embodiment of inventive concepts. FIGS. 6A and 6B are cross-sectional views taken along lines I-I′ and II-II′ of FIG. 5, respectively. In the following description of FIGS. 5, 6A, and 6B, descriptions of technical characteristics, which are substantially the same as those described above with respect to FIGS. 1-4, will be omitted or mentioned briefly.

Referring to FIGS. 5, 6A, and 6B, a semiconductor substrate 100 includes cell array regions CAR and well drive regions WDR. In at least one example embodiment, each of the cell array regions CAR may be disposed between adjacent well drive regions WDR. As shown in FIG. 5, some of the well drive regions WDR may be disposed between the cell array regions CAR, and other well drive regions WDR may be disposed around the cell array regions CAR. The semiconductor substrate 100 includes a well impurity layer 101 of a first conductivity type. The well impurity layer 101 is disposed in the semiconductor substrate 100, and the cell array regions CAR and the well drive regions WDR may be disposed in the well impurity layer 101.

In at least one example embodiment, a well drive line WDL may cross bit lines BL in a plan view. In other words, the well drive line WDL may be substantially parallel to word lines WL. The well drive line WDL may be disposed over a string selection line SSL to minimize a vertical parasitic capacitance between the well drive line WDL and the word lines WL. Alternatively, according to another example embodiment, the well drive line WDL may be disposed over the word line WL.

In at least one example embodiment, the well drive line WDL may be disposed between the word lines WL and the bit lines BL inform a vertical perspective view. In other words, a vertical distance between the top surface of the well impurity layer 101 and the well drive line WDL may be substantially equal to a vertical distance between the top surface of the well impurity layer 101 and the common source line CSL. That is, the well drive line WDL and the common source line CSL may be directly on the first interlayer insulating layer 110. The bit lines BL may cross over the well drive line WDL. In other words, the bit lines BL may be disposed on the second interlayer insulating layer 120 covering the common source line CSL and the well drive line WDL.

The well drive line WDL may be electrically connected to the well impurity layer 101 through well contact plugs WPLG and well pick-up regions 105. The well pick-up regions 105 may be locally formed in the well impurity layer 101 in the well drive regions WDR and be electrically connected to the well contact plugs WPLG.

Additionally, in the well drive regions WDR between the cell array regions CAR, the well pick-up region 105 may be formed at a side of the string selection line SSL. A well conductive pad WPAD may be disposed in the well drive region WDR between the cell array regions CAR in a plan view. The well conductive pad WPAD may be electrically connected to the well drive line WDL through a well drive via WVIA.

In at least one example embodiment, since the bit lines BL cross over the well drive line WDL, an overlapping area of the bit line BL and the well drive line WDL may be reduced in a plan view. Thus, it is possible to suppress fluctuation of the voltage applied to the bit line BL that is caused by a vertical parasitic capacitance between the bit line BL and the well drive line WDL during the operation of the semiconductor memory device.

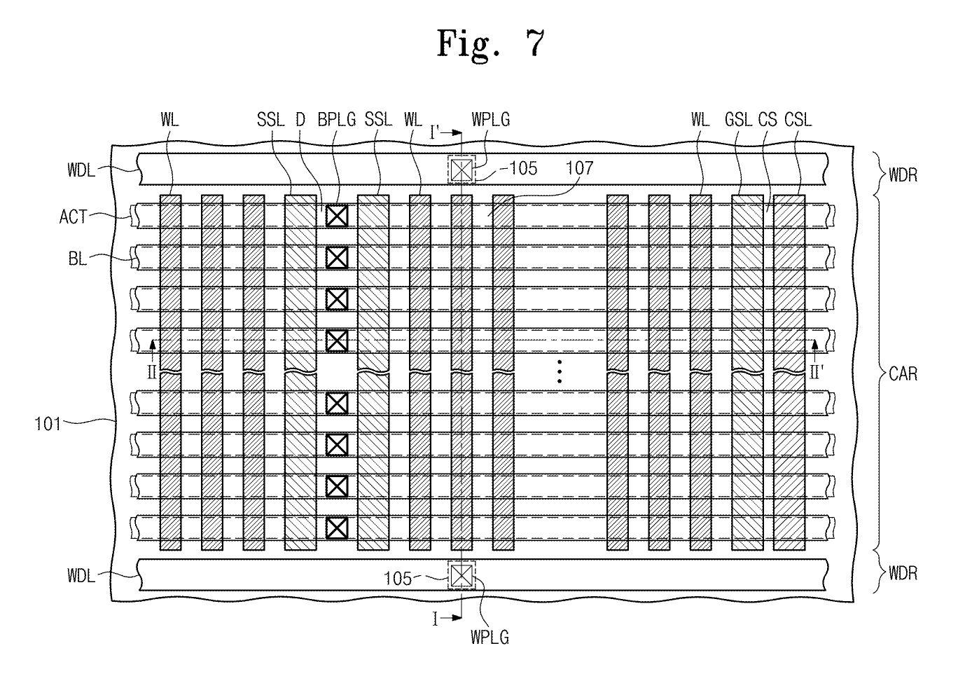

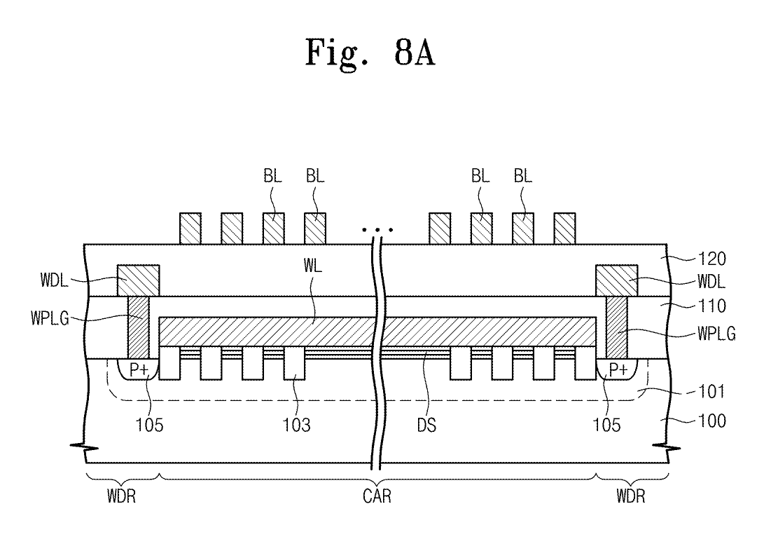

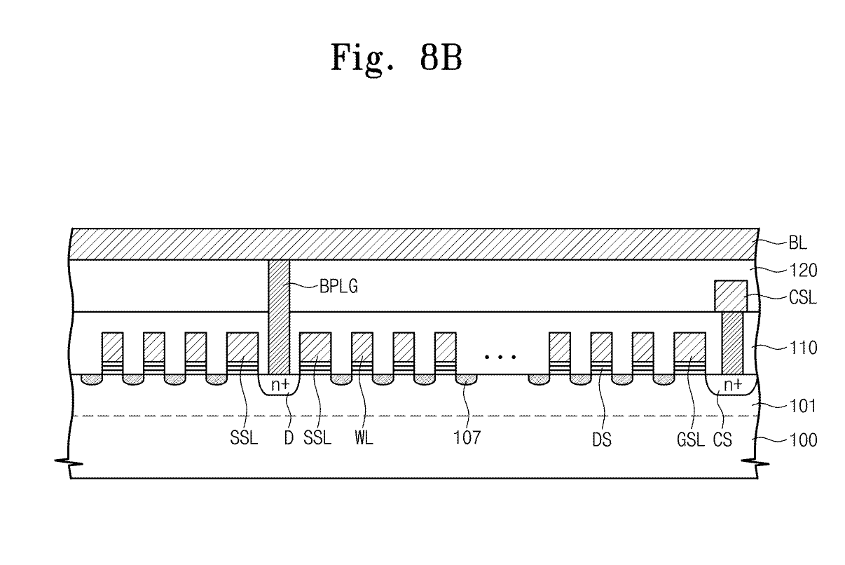

Hereinafter, a semiconductor memory device according to another example embodiment of inventive concepts will be described with reference to FIGS. 7, 8A, and 8B.

FIG. 7 is a plan view illustrating a semiconductor memory device according to at least one example embodiment of inventive concepts. FIGS. 8A and 8B are cross-sectional views taken along lines I-I′ and II-IF of FIG. 7, respectively.

In FIGS. 7, 8A, and 8B, descriptions of technical characteristics, which are substantially the same as those described above, will be omitted or mentioned briefly.

Referring to FIGS. 7, 8A, and 8B, the well impurity layer 101 includes a center portion and an edge portion around the center portion. In an example embodiment, the cell array region CAR may be disposed in the center portion of the well impurity layer 101 and the well drive regions WDR may be disposed in the edge portion of the well impurity layer 101. As illustrated in FIGS. 7, 8A, and 8B, the cell array region CAR may be disposed between the well drive regions WDR.

In at least one example embodiment, the well drive line WDL may be substantially parallel to the bit lines BL. The well drive line WDL may be locally disposed in each of the well drive regions WDR. The well drive line WDL may be electrically connected to the well impurity layer 101 through a well contact plug WPLG and a well pick-up region 105. The well pick-up region 105 may be locally formed in the edge portion of the well impurity layer 101.

Additionally, the well drive line WDL may be disposed between the bit lines BL and the word lines WL from a cross sectional perspective view. In other words, the well drive line WDL and the common source line CSL may be directly on the first interlayer insulating layer 110.

In an example embodiment, since the well drive line WDL is disposed in the well drive region WDR disposed around the cell array region CAR, the well drive line WDL is not overlapped with the bit lines BL in a plan view. Thus, it is possible to reduce (or alternatively, prevent) fluctuation of the voltage applied to the bit line BL that is caused by a desired (or alternatively, predetermined) voltage applied to the well drive line WDL.

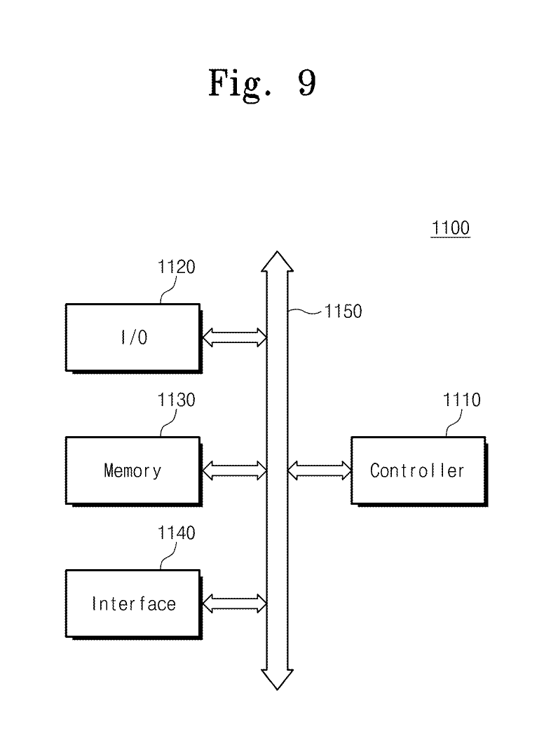

FIG. 9 is a schematic block diagram illustrating an example of memory systems including semiconductor memory devices according to at least one example embodiment of inventive concepts.

Referring to FIG. 9, a memory system 1100 can be applied to a personal digital assistant (PDA), a portable computer, a web tablet, a wireless phone, a mobile phone, a digital music player, a memory card, and/or all the devices that can transmit and/or receive data in a wireless communication environment.

The memory system 1100 includes a controller 1110, an input/output device 1120 such as a keypad and a display device, a memory device 1130, an interface 1140 and a bus 1150. The memory device 1130 and the interface 1140 communicate with each other through the bus 1150.

The controller 1110 includes at least one microprocessor, at least one digital signal processor, at least one micro controller or other process devices similar to the microprocessor, the digital signal processor and the micro controller. The memory device 1130 may be used to store an instruction executed by the controller 1110. The input/output device 1120 can receive data or a signal from the outside of the information processing system 1100 or transmit data or a signal to the outside of the information processing system 1100. For example, the input/output device 1120 may include a keyboard, a keypad and/or a displayer.

The memory device 1130 includes the 3D semiconductor device according to embodiments of the inventive concept. The memory device 1130 may further include different kinds of memory devices. For example, the memory device 1130 may further include at least one of a volatile memory device capable of randomly accessing, and other various kinds of memory devices.

The interface 1140 transmits data to a communication network or receives data from a communication network.

The semiconductor memory devices and/or the memory systems according to inventive concepts may be encapsulated using various packaging techniques. For example, the semiconductor memory devices and/or the memory systems according to the aforementioned embodiments may be encapsulated using any one of a package on package (POP) technique, a ball grid arrays (BGAs) technique, a chip scale packages (CSPs) technique, a plastic leaded chip carrier (PLCC) technique, a plastic dual in-line package (PDIP) technique, a die in waffle pack technique, a die in wafer form technique, a chip on board (COB) technique, a ceramic dual in-line package (CERDIP) technique, a plastic metric quad flat package (PMQFP) technique, a plastic quad flat package (PQFP) technique, a small outline package (SOIC) technique, a shrink small outline package (SSOP) technique, a thin small outline package (TSOP) technique, a thin quad flat package (TQFP) technique, a system in package (SIP) technique, a multi chip package (MCP) technique, a wafer-level fabricated package (WFP) technique and a wafer-level processed stack package (WSP) technique, etc.

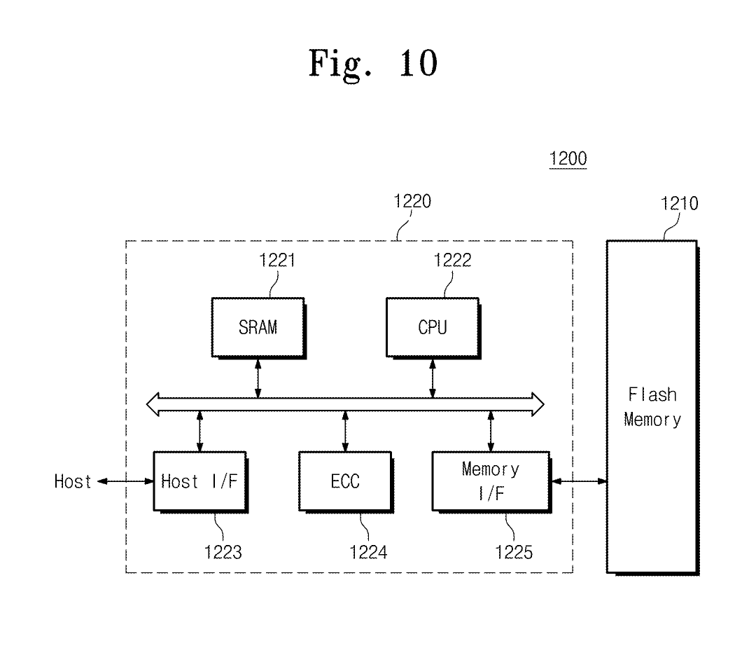

FIG. 10 is a schematic block diagram illustrating an example of memory cards including semiconductor memory devices according to at least one example embodiment of inventive concepts.

Referring to FIG. 10, a memory card 1200 having a storage capability of a large capacity includes a flash memory device 1210. The flash memory device 1210 includes the semiconductor memory device according to aforementioned example embodiments. The memory card 1200 according to an example embodiment of inventive concepts includes a memory controller 1220 controlling every data exchange between a host and the flash memory device 1210.

A static random access memory (SRAM) 1221 is used as an operation memory of a processing unit 1222. A host interface 1223 includes data exchange protocols of a host to be connected to the memory card 1200. An error correction block 1224 detects and corrects errors included in data readout from a multi bit flash memory device 1210. A memory interface 1225 interfaces with the flash memory device 1210 of at least one example embodiment of inventive concepts. The processing unit 1222 performs every control operation for exchanging data of the memory controller 1220. Even though not depicted in drawings, it is apparent to one of ordinary skill in the art that the memory card 1200 according to at least one example embodiment of inventive concepts can further include a ROM (not shown) storing code data for interfacing with the host.

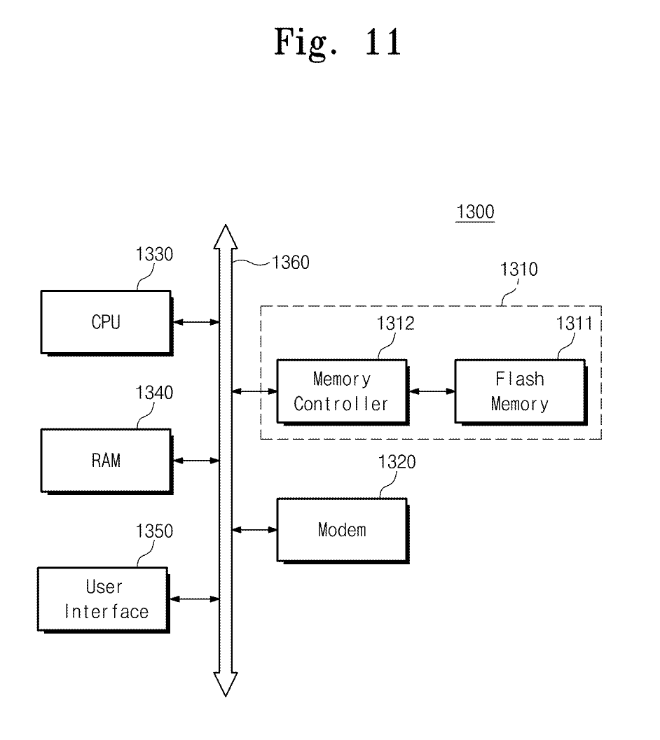

FIG. 11 is a schematic block diagram illustrating an example of information processing systems including semiconductor memory devices according to at least one example embodiment of inventive concepts.

Referring to FIG. 11, a flash memory system 1310 is built in a data processing system such as a mobile product or a desk top computer. The flash memory system 1310 includes the 3D semiconductor memory device according to an example embodiment of inventive concepts. The data processing system 1300 according to inventive concepts includes the flash memory system 1310 and a modem 1320, a central processing unit 1330, a RAM, a user interface 1350 that are electrically connected to a system bus 1360. The flash memory system 1310 may be constructed so as to be identical to the memory system or the flash memory card described above. The flash memory system 1310 stores data processed by the central processing unit 1330 or data inputted from an external device. The flash memory system 1310 may include a solid state disk (SSD) and in this case, the data processing system 1310 can stably store large amounts of data in the flash memory system 1310. As reliability is improved, the flash memory system 1310 can reduce resources used to correct errors, thereby providing a high speed data exchange function to the data processing system 1300. Even though not depicted in the drawings, it is apparent to one of ordinary skill in the art that the data processing unit 1300 according to at least one example embodiment of inventive concepts may further include an application chipset, a camera image processor (CIS) and/or an input/output device.

The semiconductor memory devices according to at least one example embodiment described above may reduce an overlapping area of the well drive line applying a desired (or alternatively, predetermined) voltage to the well impurity layer and bit lines in a plan view. Thus, it is possible to reduce a vertical parasitic capacitance between the well drive line and the bit lines. As a result, it is possible to reduce (or alternatively, prevent) an operation error of the semiconductor memory device which is generated due to a voltage fluctuation of the voltage applied to the bit lines caused by the parasitic capacitance when the semiconductor memory device is operated. Thus, reliability of the semiconductor memory device may be improved.

While inventive concepts have been described with reference to example embodiments, it will be apparent to those skilled in the art that various changes and modifications may be made without departing from the spirit and scope of inventive concepts. Therefore, it should be understood that the above example embodiments are not limiting, but illustrative. Thus, the scope of inventive concepts is to be determined by the broadest permissible interpretation of the following claims and their equivalents, and shall not be restricted or limited by the foregoing description.

What is claimed is:

1. A semiconductor memory device comprising:
a well impurity layer including a cell array region and a well drive region adjacent to the cell array region, the well impurity layer having a first conductivity type;
at least one word line on the well impurity layer;
at least one bit line crossing the at least one word line on the well impurity layer of the cell array region, the at least one bit line connected to a drain region in the well impurity layer, and the drain region having a second conductivity type; and
a well drive line crossing the at least one word line on the well impurity layer of the well drive region, the well drive line connected to the well impurity layer of the first conductivity type.

2. The semiconductor memory device of claim 1, wherein the well drive line is between the at least one bit line and an adjacent bit line from a plan view perspective; and a width of the well drive line is smaller than a distance between the at least one bit line and the adjacent bit line.

3. The semiconductor memory device of claim 1, wherein a width of the well drive line is greater than a width of the at least one bit line.

4. The semiconductor memory device of claim 1, wherein the well drive line is between the at least one bit line and the at least one word line from a cross-sectional perspective view.

5. The semiconductor memory device of claim 1, wherein the well drive line is disposed over a center portion of the well impurity layer.

6. The semiconductor memory device of claim 1, wherein the well drive line is disposed over an edge portion of the well impurity layer and the at least one bit line is disposed over a center portion of the well impurity layer.

7. The semiconductor memory device of claim 1, further comprising:
a well pick-up region in the well impurity layer, the well pick-up region having the first conductivity type, and an impurity concentration of the well pick-up region being greater than that of the well impurity layer; and
a contact plug connecting the well drive line to the well pick-up region.

8. The semiconductor memory device of claim 7, further comprising:
at least one string selection line on the well impurity layer and parallel to the at least one word line, and the drain region and the well pick-up region are disposed at a side of the at least one string selection line, the drain region and the well pick-up region being spaced apart from the at least one string selection line.

9. The semiconductor memory device of claim 1, further comprising:
a common source region in the well impurity layer of the cell array region, the common source region having the second conductivity type; and
a common source conductive pad covering a top surface of the at least one bit line, the common source conductive pad applying a desired voltage to the common source region.

10. A semiconductor memory device comprising:
a well impurity layer of a first conductivity type;
at least one word line on the well impurity layer;
at least one bit line crossing the at least one word line, the at least one bit line connected to a drain region formed in the well impurity layer, the drain region having a second conductivity type; and
a well drive line crossing the at least one bit line at a height different from that of the at least one bit line with respect to a top surface of the well impurity layer, the well driving line being connected to the well impurity layer.

11. The semiconductor memory device of claim 10, wherein the well drive line is between the at least one bit line and the at least one word line from a cross-sectional perspective view.

12. The semiconductor memory device of claim 10, further comprising:
a well pick-up in the well impurity layer, the well pick-up region having the first conductivity type, and an impurity concentration of the well pick-up region being greater than that of the well impurity layer; and
a contact plug connecting the well drive line to the well pick-up region.

13. The semiconductor memory device of claim 12, wherein the well pick-up region is in an edge portion of the well impurity layer.

14. The semiconductor memory device of claim 12, further comprising:
at least one string selection line on the well impurity layer and substantially parallel to the at least one word line, the well drive line being disposed over the at least one string selection line.

15. The semiconductor memory device of claim 14, wherein the well pick-up region is in a portion of the well impurity layer at a side of the at least one string selection line from a plan view perspective.

16. A semiconductor memory device comprising,
a well impurity layer;
a word line on the well impurity layer;
a bit line on the well impurity layer, the bit line crossing the word line; and
a well drive region including a well drive line, the well drive line being parallel to one of the word line and the bit line, and the well drive line and the bit line being at different vertical levels in the semiconductor memory device.

17. The semiconductor memory device of claim 16, further comprising:
a region of the well impurity layer having a first conductivity type connected to the bit line; and
a region of well impurity layer having a second conductivity type connected to the well drive line, the second conductivity type being opposite the first conductivity type.

18. The semiconductor memory device of claim 17, further comprising:
a dummy pattern on the well drive region; and
a common source line connected to the dummy pattern, the common source line connected to a region having the first conductivity type in the well impurity layer.

19. The semiconductor memory device of claim 16, wherein the well drive region is in a center portion of the well impurity layer.

20. The semiconductor memory device of claim 16, wherein the well drive region is in an edge portion of the well impurity layer.
